(19) United States
(12) Patent Application Publication
(10) Pub. No.: US 2010/0112786 A1
(43) Pub. Date: May 6, 2010

(54) METHOD OF MANUFACTURING SEMICONDUCTOR DEVICE

(75) Inventor: Takuya Kazama, Nagano-shi (JP)

Correspondence Address: RANKIN, HILL & CLARK LLP, 38210 Glenn Avenue, WILLOUGHBY, OH, 44094-7808, US

(73) Assignee: SHINKO ELECTRIC INDUSTRIES CO., LTD., Nagano-shi (JP)

(21) Appl. No.: 12/608,296

(22) Filed: Oct. 29, 2009

(30) Foreign Application Priority Data
Oct. 30, 2008 (JP) 2008-280171

(51) Int. Cl. H01L 21/78

(52) U.S. Cl. 438/460; 257/E21.599

(57) ABSTRACT

A semiconductor substrate has a plurality of semiconductor chip forming areas and scribe areas including substrate cutting positions arranged between the plurality of semiconductor chip forming areas. An insulating layer having first opening portions, which expose all or a part of the scribe areas respectively, is formed on the semiconductor substrate. A solder resist layer having second opening portions, which expose all or a part of the scribe areas respectively, is formed on the insulating layer. Portions of the semiconductor substrate corresponding to the substrate cutting positions are cut.

This application claims priority to Japanese Patent Application No. 2008-280171, filed Oct. 30, 2008, in the Japanese Patent Office. The Japanese Patent Application No. 2008-280171 is incorporated by reference in its entirety.

### TECHNICAL FIELD

The present disclosure relates to a method of manufacturing a semiconductor device, including a step of forming an insulating layer on a semiconductor substrate and a step of cutting the semiconductor substrate.

### RELATED ART

Out of the semiconductor devices in the related art, there is the semiconductor device that is called the chip-size package whose size is substantially identical to the semiconductor chip when viewed from the top (see FIG. 1, for example).

FIG. 1 is a sectional view showing the semiconductor device in the related art. By reference to FIG. 1, a semiconductor device 100 in the related art includes a semiconductor chip 101, internal connection terminals 102, an insulating layer 103, wiring patterns 104, a solder resist layer 106, and external connection terminals 107.

The semiconductor chip 101 has a semiconductor substrate 109, a plurality of electrode pads 112, and a protection film 113. The semiconductor substrate 109 is obtained by dicing a Si wafer that is thinned, for example. A semiconductor integrated circuit 111 is formed on one side of the semiconductor substrate 109.

The semiconductor integrated circuit 111 has diffusion layers (not shown), an insulating layer (not shown), via holes (not shown), wirings (not shown), and the like. A plurality of electrode pads 112 are provided onto one surface (a surface on the side on which the semiconductor integrated circuit 111 is formed) of the semiconductor substrate 109. A plurality of electrode pads 112 are connected electrically to wirings (not shown) that are provided on the semiconductor integrated circuit 111. The protection film 113 is provided on one surface (a surface on the side on which the semiconductor integrated circuit 111 is formed) of the semiconductor substrate 109. The protection film 113 is the film that is used to protect the semiconductor integrated circuit 111.

The internal connection terminal 102 is provided on the electrode pads 112 respectively. Upper surfaces 102A of the internal connection terminals 102 are exposed from the insulating layer 103. The upper surface 102A of the internal connection terminal 102 is connected to the wiring patterns 104 respectively. The insulating layer 103 is provided to cover the semiconductor chip 101 on the side on which of the internal connection terminal 102 is provided.

The wiring patterns 104 are provided on an upper surface 103A of the insulating layer 103. The wiring pattern 104 is connected to the internal connection terminals 102 respectively. The wiring patterns 104 are connected electrically to the electrode pads 112 via the internal connection terminals 102. The solder resist layer 106 is provided on the upper surface 103A of the insulating layer 103 to cover the wiring patterns 104. The solder resist layer 106 has opening portions 106X from which a part of the wiring pattern 104 is exposed.

The external connection terminal 107 is provided on the wiring patterns 104 exposed from the opening portions 106X in the solder resist layer 106 respectively. The external connection terminals 107 are the terminals that are connected electrically to pads provided to the mounting substrate (not shown) such as the motherboard, or the like, for example.

FIG. 2 is a plan view showing a semiconductor substrate in which the semiconductor device in the related art is formed. In FIG. 2, C denotes a position in which the dicer cuts a semiconductor substrate 110 into individual pieces (referred to as a “substrate cutting position C” hereinafter). By reference to FIG. 2, the semiconductor substrate 110 has a plurality of semiconductor chip forming areas A and scribe areas B along which a plurality of semiconductor chip forming areas A are separated. A plurality of semiconductor chip forming areas A correspond to the areas in which the semiconductor chip 101 is formed respectively. The semiconductor substrate 110 gives the semiconductor substrates 109 (see FIG. 1) explained above when such substrate is shaped into a thin plate and is cut along the substrate cutting position C.

FIG. 3 to FIG. 11 are views showing steps of manufacturing the semiconductor device in the related art. In FIG. 3 to FIG. 11, the same reference symbols are affixed to the same constituent portions as the semiconductor device 100 in FIG. 1 in the related art and in some cases their explanation is omitted herein. Also, in FIG. 3 to FIG. 11, A denotes each of a plurality of semiconductor chip forming areas (referred to as a “semiconductor chip forming area A” hereinafter), B denotes a scribe area along which a plurality of semiconductor chip forming areas are separated (referred to as a “scribe area B” hereinafter), and C denotes a position in which the dicing blade cuts the semiconductor substrate 110 into individual pieces (referred to as a “substrate cutting position C” hereinafter).

At first, in steps shown in FIG. 3, the semiconductor chip 101 is formed. In other words, the semiconductor integrated circuit 111 is formed on one side of the semiconductor substrate 110 before this substrate is thinned, and then a plurality of electrode pads 112 and the protection film 113 are formed on one surface (a surface on the side on which the semiconductor integrated circuit 111 is formed) of the semiconductor substrate 110. In this case, the protection film 113 is formed on the portion of the semiconductor substrate 110 except the scribe area B on one surface of the semiconductor substrate 110.

Then, in steps shown in FIG. 4, the internal connection terminal 102 is formed on a plurality of electrode pads 112 respectively. In this stage, there is variation in a height of a plurality of internal connection terminals 102. Then, in steps shown in FIG. 5, respective heights of a plurality of internal connection terminals 102 are made uniform by pushing a flat plate 115 against a plurality of internal connection terminals 102. Then, in steps shown in FIG. 6, the insulating layer 103 made of a resin is formed to cover the side of the semiconductor chip 101, on which the internal connection terminals 102 are formed, and the internal connection terminals 102. Since the insulating layer 103 is formed on the whole area of one surface of the semiconductor substrate 110, the whole area of one surface of the semiconductor substrate 110 including the scribe area B is covered with the insulating layer 103.

Then, in steps shown in FIG. 7, the insulating layer 103 is polished until the upper surface 102A of the internal connection terminal 102 is exposed from the insulating layer 103. At this time, the polishing is applied such that the upper surface 103A of the insulating layer 103 and the upper surface 102A of the internal connection terminal 102 constitute substantially the coplanar surface. Accordingly, an upper surface of a structure shown in FIG. 7 (concretely, the upper surface 103A of the insulating layer 103 and the upper surface 102A of the internal connection terminal 102) is made flat.

Then, in steps shown in FIG. 8, the wiring patterns 104 are formed on the upper surface, which is made flat, of the structure shown in FIG. 7. Concretely, the wiring patterns 104 are formed, for example, by pasting a metallic foil (not shown) on the structure shown in FIG. 7, then coating a resist (not shown) to cover the metallic foil, and then forming a resist film (not shown) on the portion of the metallic foil, which corresponds to the forming areas of the wiring patterns 104, by exposing/developing this resist. Then, the metallic foil is etched by using the resist film as a mask, so that the wiring patterns 104 are formed (the subtractive method). Then, the resist film is removed.

Then, in steps shown in FIG. 9, the solder resist layer 106 having the opening portions 106X, from which a part of the wiring patterns 104 is exposed respectively, is formed to cover the wiring patterns 104 and the upper surface 103A of the insulating layer 103. Since the solder resist layer 106 is formed on one surface of the semiconductor substrate 110, the whole area of one surface of the semiconductor substrate 110 containing the scribe areas B is covered with the solder resist layer 106.

Then, in steps shown in FIG. 10, the semiconductor substrate 110 is thinned by polishing the other surface (a surface on the side on which the semiconductor integrated circuit 111 is not formed) of the semiconductor substrate 110. Then, in steps shown in FIG. 11, the external connection terminal 107 is formed on the wiring patterns 104 exposed in the opening portions 106X, respectively.

Then, the semiconductor substrate 110 is diced along the portions corresponding to the substrate the cutting positions C, so that a plurality of semiconductor devices 100 are manufactured. At this time, the insulating layer 103 and the solder resist layer 106 are formed on one surface of the portions, which correspond to the scribe areas B, of the semiconductor substrate 110, and therefore the insulating layer 103 and the solder resist layer 106 are cut together with the semiconductor substrate 110.
[Patent Literature 1] JP-A-2002-313985
[Patent Literature 2] JP-A-2000-21823

However, in the semiconductor device 100 in the related art, the adhesion between the semiconductor substrate 110 and the insulating layer 103 is poor because their physical properties are different mutually. Therefore, when the insulating layer 103 and the solder resist layer 106 are cut along the substrate cutting position C together with the semiconductor substrate 110 corresponding to the scribe area B, the peeling is caused at the boundary between the semiconductor substrate 110 and the insulating layer 103.

### SUMMARY

Exemplary embodiments of the present invention provide a method of manufacturing a semiconductor device, capable of suppressing a peeling that is caused due to a cutting at a boundary between a semiconductor substrate and an insulating layer.

A method of manufacturing a semiconductor device according to an exemplary embodiment of the invention, comprises:

a first step of preparing a semiconductor substrate that has a plurality of semiconductor chip forming areas and scribe areas including substrate cutting positions arranged between the plurality of semiconductor chip forming areas;

a second step of forming an insulating layer having first opening portions, which expose all or a part of the scribe areas respectively, on the semiconductor substrate;

a third step of forming a solder resist layer having second opening portions, which expose all or a part of the scribe areas respectively, on the insulating layer; and

a fourth step of cutting portions of the semiconductor substrate corresponding to the substrate cutting positions.

According to the disclosed method, it is possible to provide the method of manufacturing the semiconductor device, capable of suppressing the peeling that is caused due to the cutting at the boundary between the semiconductor substrate and the insulating layer.

Other features and advantages may be apparent from the following detailed description, the accompanying drawings and the claims.

### BRIEF DESCRIPTION OF THE DRAWINGS

FIG. 1 is a sectional view showing the semiconductor device in the related art.

FIG. 2 is a plan view showing a semiconductor substrate in which the semiconductor device in the related art is formed.

FIG. 3 to FIG. 11 are views showing steps of manufacturing the semiconductor device in the related art.

FIG. 12 is a sectional view of a semiconductor device according to a first embodiment of the present invention.

FIG. 13 is a plan view of a semiconductor substrate on which the semiconductor device according to the first embodiment of the present invention is formed.

FIG. 14 to FIG. 29 are views showing steps of manufacturing the semiconductor device according to the first embodiment of the present invention.

FIG. 30 and FIG. 31 are views showing steps of manufacturing a semiconductor device according to the variation 1 of the first embodiment of the present invention.

FIG. 32 to FIG. 35 are views showing steps of a variation 2 of the first embodiment of the present invention.

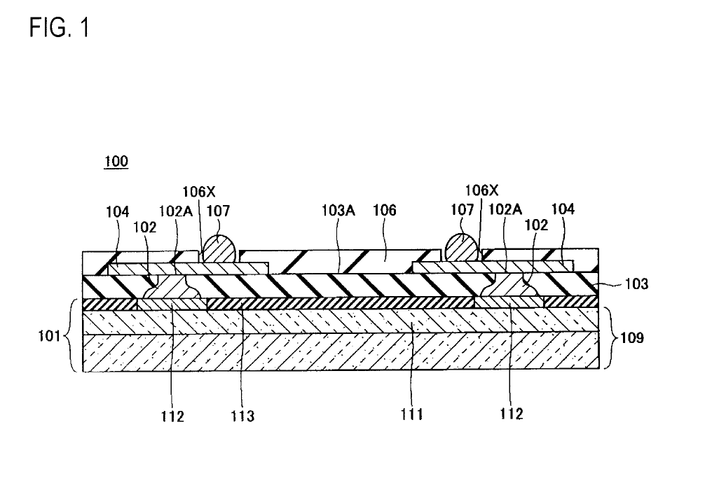

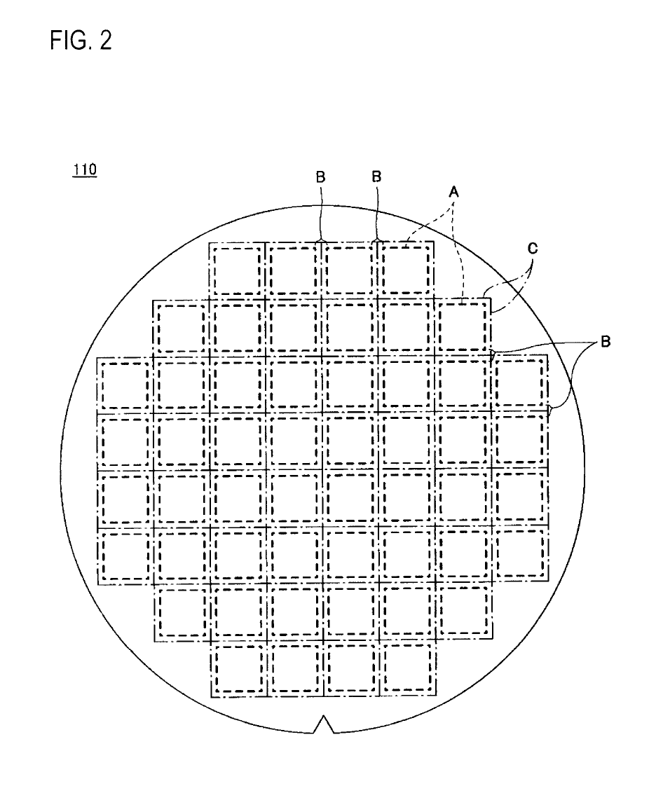

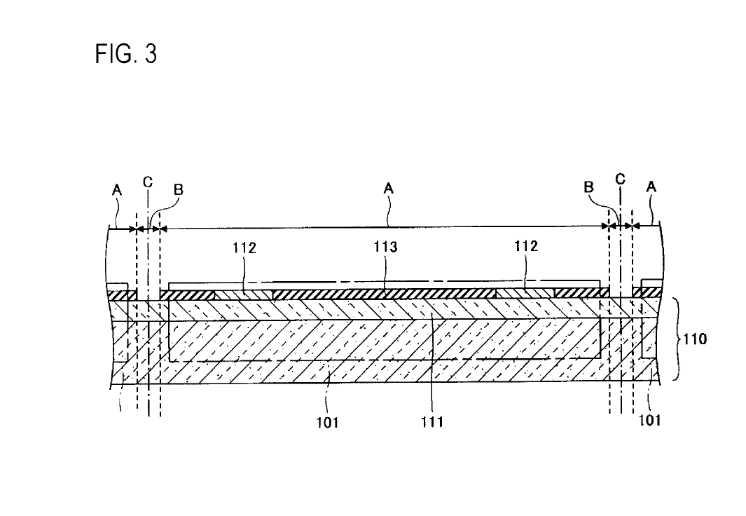

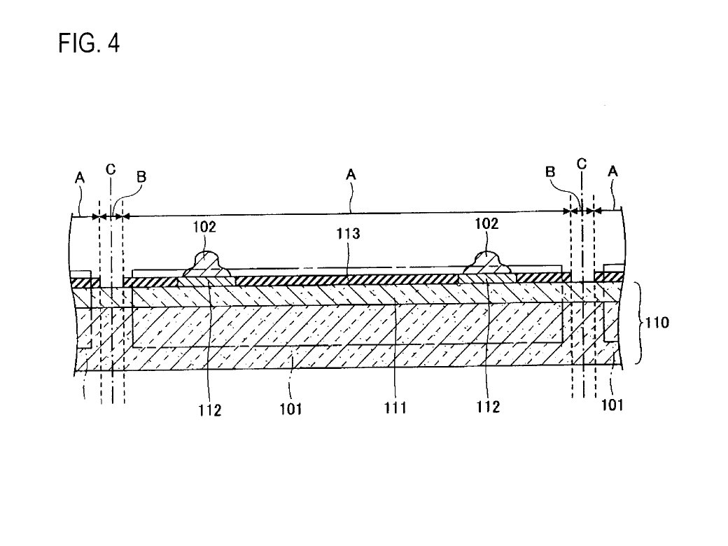

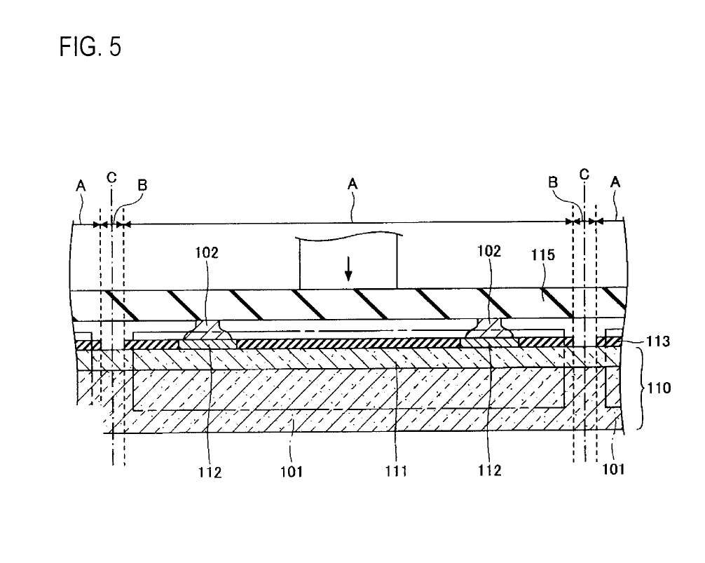

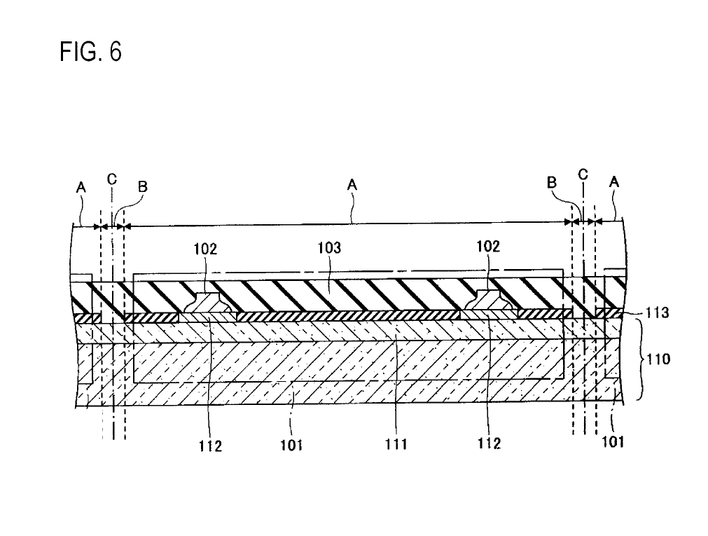

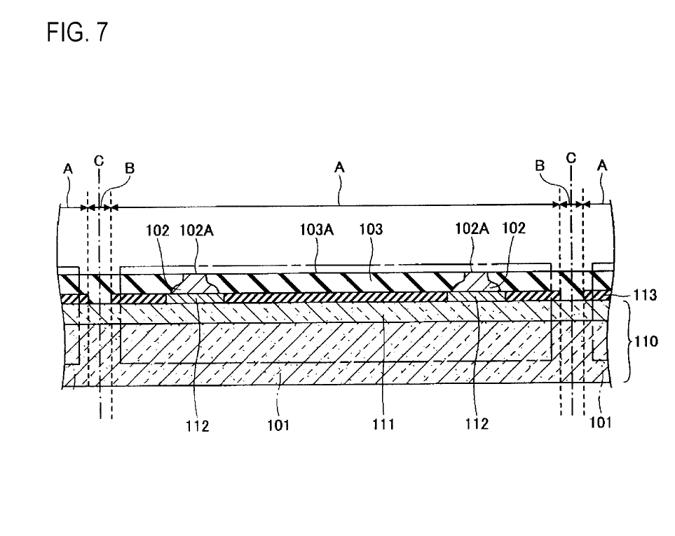

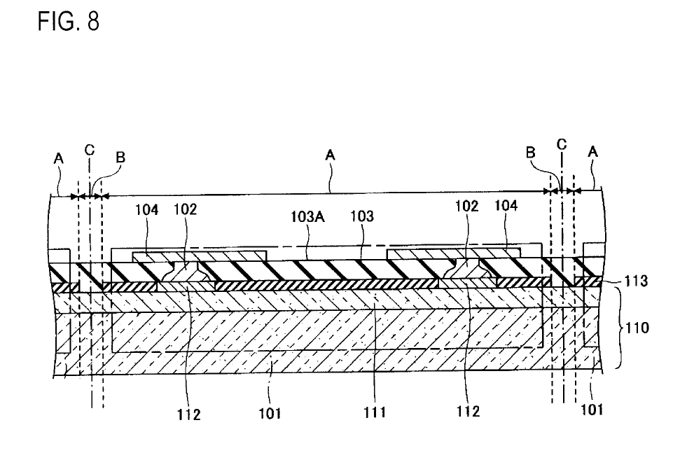

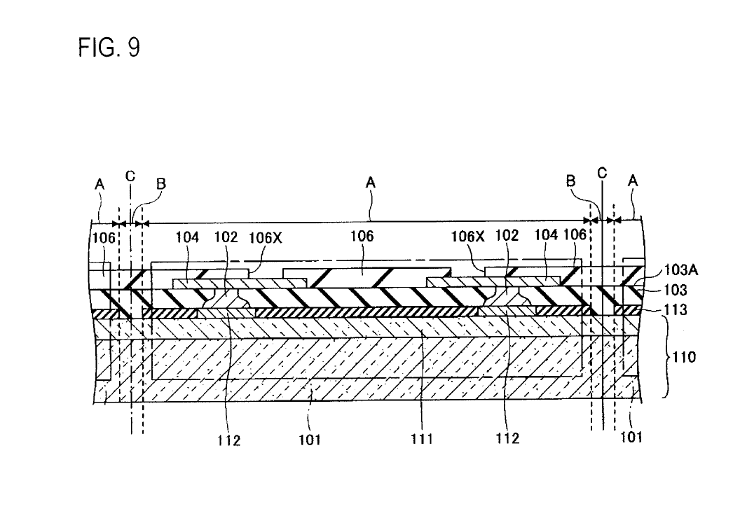

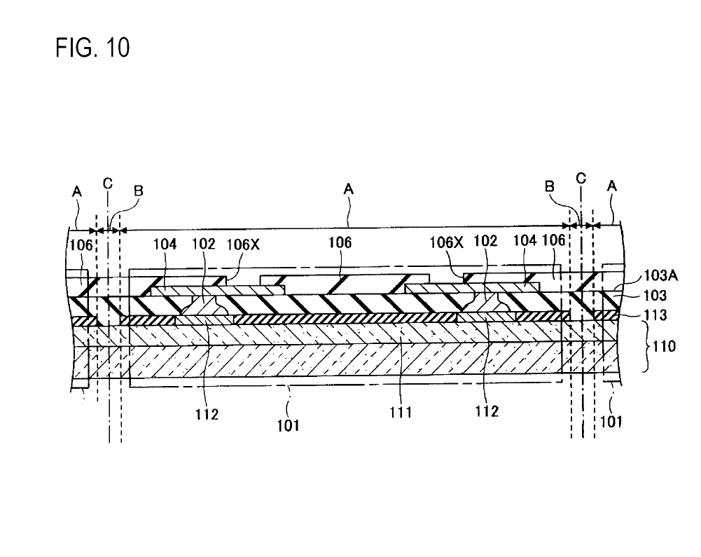

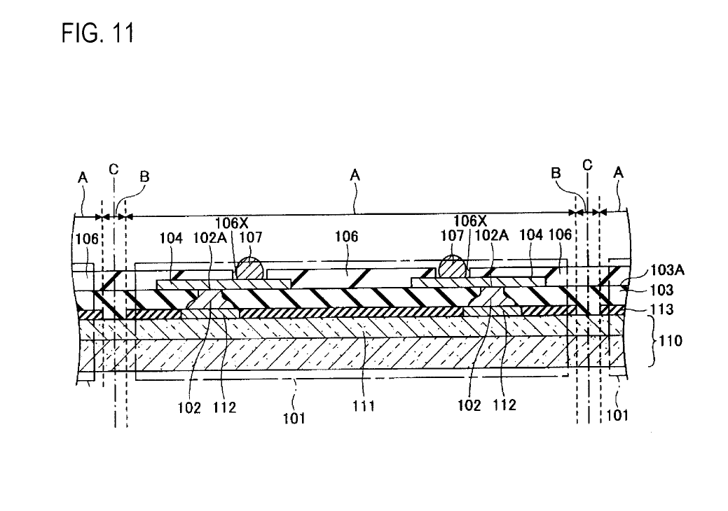

### DETAILED DESCRIPTION

The best mode for carrying out the present invention will be explained with reference to the drawings hereinafter.

### First Embodiment

### Configuration of Semiconductor Device in First Embodiment of Present Invention

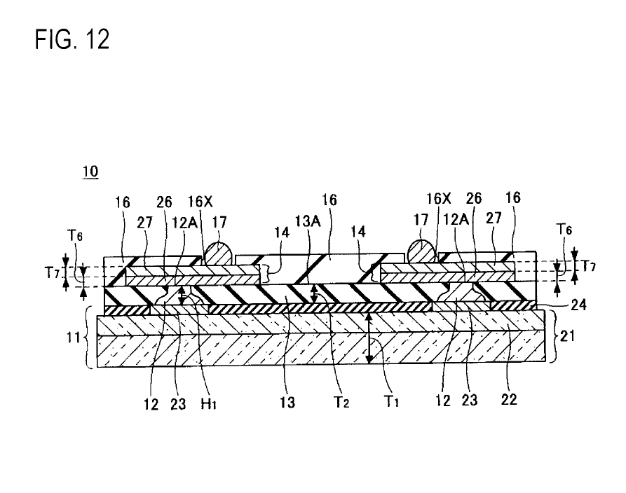

At first, a configuration of a semiconductor device according to a first embodiment of the present invention will be explained hereinafter. FIG. 12 is a sectional view of a semiconductor device according to a first embodiment of the present invention. By reference to FIG. 12, a semiconductor device 10 of the first embodiment includes a semiconductor chip 11, internal connection terminals 12, an insulating layer 13, wiring patterns 14, a solder resist layer 16, and external connection terminals 17.

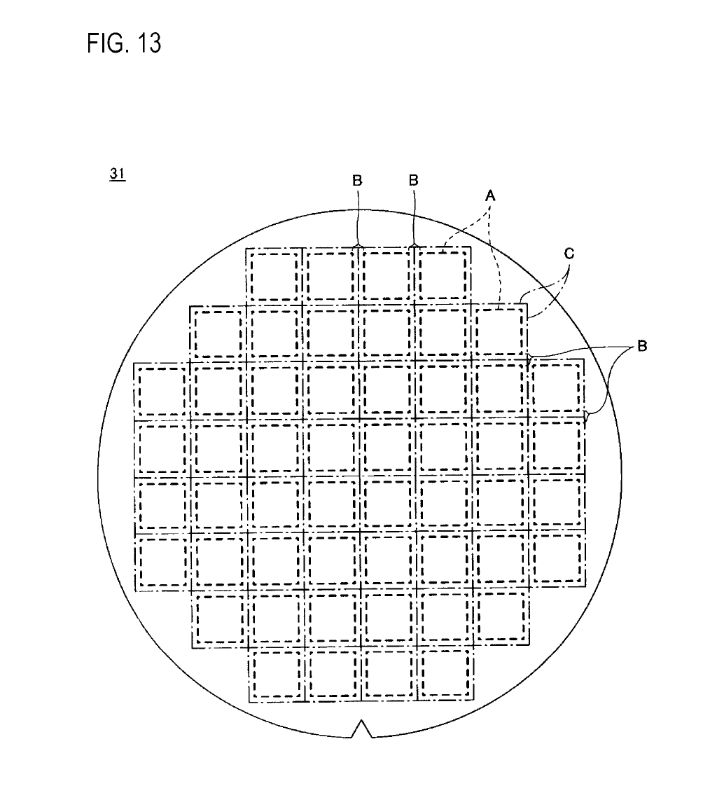

FIG. 13 is a plan view of a semiconductor substrate on which the semiconductor device according to the first embodiment of the present invention is formed. In FIG. 13, 31 denotes a semiconductor substrate, and C denotes a position in which the dicer cuts a semiconductor substrate 31 into individual pieces (referred to as a “substrate cutting position C” hereinafter). The semiconductor substrate 31 has a plurality of semiconductor chip forming areas A and scribe areas B containing the substrate cutting positions C along which a plurality of semiconductor chip forming areas A are separated. A plurality of semiconductor chip forming areas A correspond to the areas in which the semiconductor chip 11 is formed respectively. The semiconductor substrate 31 gives a semiconductor substrate 21 shown in FIG. 12 when such substrate is shaped into a thin plate and is cut along the substrate cutting position C.

In FIG. 12, the semiconductor chip 11 has the semiconductor substrate 21, a plurality of electrode pads 23, and a protection film 24. A semiconductor integrated circuit 22 is formed on one side of the semiconductor substrate 21. The semiconductor substrate 21 is shaped in a thin plate. A thickness T₁ of the semiconductor substrate 21 can be set to 100 μm to 300 μm, for example. The semiconductor substrate 21 is obtained by dicing a thinned Si wafer, for example, into individual pieces.

The semiconductor integrated circuit 22 has diffusion layers (not shown), an insulating layer (not shown), via holes (not shown) provided in the insulating layer, wirings (not shown), and the like.

The electrode pads 23 are provided onto one surface (a surface on the side on which the semiconductor integrated circuit 22 is formed) of the semiconductor substrate 21. The electrode pads 23 are connected electrically to wirings (not shown) that are provided on the semiconductor integrated circuit 22. As the material of the electrode pads 23, for example, Al, or the like can be employed.

The protection film 24 is provided on one surface (a surface on the side on which the semiconductor integrated circuit 22 is formed) of the semiconductor substrate 21. The protection film 24 is the film that is used to protect the semiconductor integrated circuit 22. As the protection film 24, for example, a SiN film, a PSG film, or the like can be employed. Also, a layer made of polyimide, or the like may be stacked on the layer formed of the SiN film, the PSG film, or the like.

The internal connection terminal 12 is provided on the electrode pads 23 respectively. The internal connection terminal 12 is provided to connect the semiconductor integrated circuit 22 and the wiring patterns 14. A height H₁ of the internal connection terminal 12 can be set to 10 μm to 60 for example. As the internal connection terminal 12, for example, Au bumps, bumps each consisting of a Ni film formed by the electroless plating and an Au film for covering this Ni film, or the like can be employed. The Au bumps can be formed by the bonding method or the plating method, for example.

The insulating layer 13 is provided to cover the internal connection terminals 12 and the semiconductor chip 11 except upper surfaces 12A of the internal connection terminals 12.

The upper surfaces 12A of the internal connection terminals 12 are exposed from the insulating layer 13. An upper surface 13A of the insulating layer 13 and the upper surfaces 12A of the internal connection terminals 12 constitute substantially the coplanar surface. As the material of the insulating layer 13, either of the photosensitive insulating material and the non-photosensitive insulating material (insulating material having no photosensitivity) may be employed. As the insulating layer 13, for example, a sheet-like insulating layer (e.g., NCF (Non Conductive Film)) having tackiness, a paste-like insulating layer (e.g., NCP (Non Conductive Paste)), or the like can be employed. A thickness T₂ of the insulating layer 13 can be set to 10 μm to 60 μm, for example.

The wiring pattern 14 consists of a metal layer 26 and a metal layer 27, and is provided on the upper surface 13A of the insulating layer 13 to contact to the upper surface 12A of the internal connection terminal 12. The wiring patterns 14 are connected electrically to the semiconductor integrated circuit 22 via the internal connection terminals 12. As the material of the wiring pattern 14, for example, Cu, or the like can be employed. A thickness of the wiring pattern 14 can be set to 12 μm, for example. The solder resist layer 16 is provided on the upper surface 13A of the insulating layer 13 to cover the wiring patterns 14. The solder resist layer 16 has opening portions 16X from which a part of the wiring pattern 14 is exposed respectively.

The external connection terminal 17 is provided on the wiring patterns 14, which are exposed from the opening portions 16X of the solder resist layer 16, respectively. The external connection terminals 17 are the terminals that are connected electrically to the pads provided to the mounting substrate (not shown) such as the motherboard, or the like, for example. As the external connection terminal 17, for example, the solder bump, or the like may be employed. As the material of the external connection terminal 17, for example, alloy containing Pb, alloy of Sn and Cu, alloy of Sn and Ag, alloy of Sn, Ag, and Cu, or the like may be employed. Also, the solder ball that employs a resin (e.g., divinylbenzene, or the like) as a core may be employed.

### Method of Manufacturing Semiconductor Device in First Embodiment of Present Invention

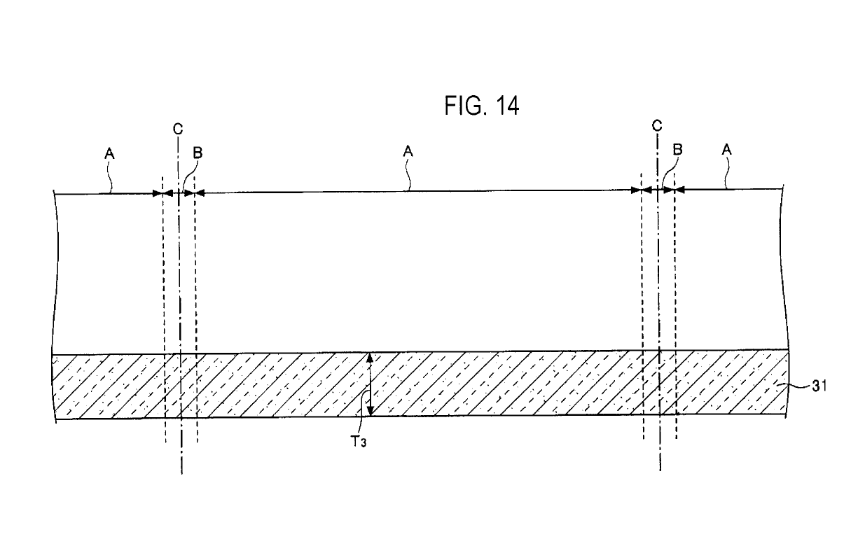

Next, a method of manufacturing the semiconductor device according to the first embodiment of the present invention will be explained hereunder. FIG. 14 to FIG. 29 are views showing steps of manufacturing the semiconductor device according to the first embodiment of the present invention. In FIG. 14 to FIG. 29, the same reference symbols are affixed to the same constituent portions as the semiconductor device 10 shown in FIG. 12 and in some cases their explanation is omitted herein.

In FIG. 14 to FIG. 29, C denotes a position in which the dicing blade cuts the semiconductor substrate 31 into individual pieces (referred to as a “substrate cutting position C” hereinafter), A denotes each of a plurality of semiconductor chip forming areas (referred to as a “semiconductor chip forming area A” hereinafter), and B denotes a scribe area containing the substrate cutting positions C along which a plurality of semiconductor chip forming areas A are separated (referred to as a “scribe area B” hereinafter).

At first, in steps shown in FIG. 14, the semiconductor substrate 31 having a plurality of semiconductor chip forming areas A and the scribe area B containing the substrate cutting positions C along which a plurality of semiconductor chip forming areas A are separated is prepared (see FIG. 13). The semiconductor substrate 31 is shaped into the semiconductor substrate 21 explained previously (see FIG. 12) when this semiconductor substrate 31 is thinned and diced in the substrate cutting positions C. As the semiconductor substrate 31, the Si wafer, or the like can be employed, for example. A thickness T₃ of the semiconductor substrate 31 can be set to 500 μm to 775 μm, for example.

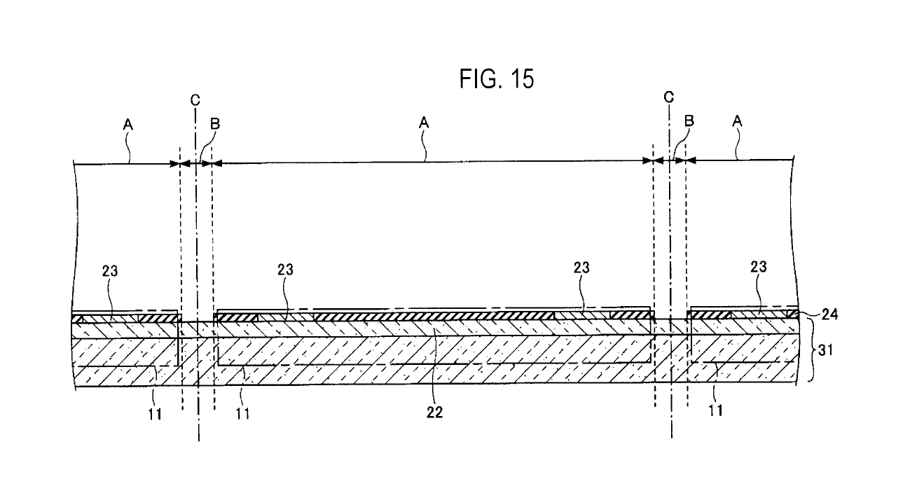

Then, in steps shown in FIG. 15, the semiconductor chip 11 is formed on one side of the semiconductor substrate 31 corresponding to the semiconductor chip forming areas A by the well-known approach. That is, the semiconductor integrated circuit 22 is formed on one side of the semiconductor substrate 31 prior to a thickness reduction, and then a plurality of electrode pads 23 and the protection film 24 are formed on one surface (a surface on the side on which the semiconductor integrated circuit 22 is formed) of the semiconductor substrate 31. In this case, the protection film 24 is formed on the portion of one surface of the semiconductor substrate 31 except the scribe area B.

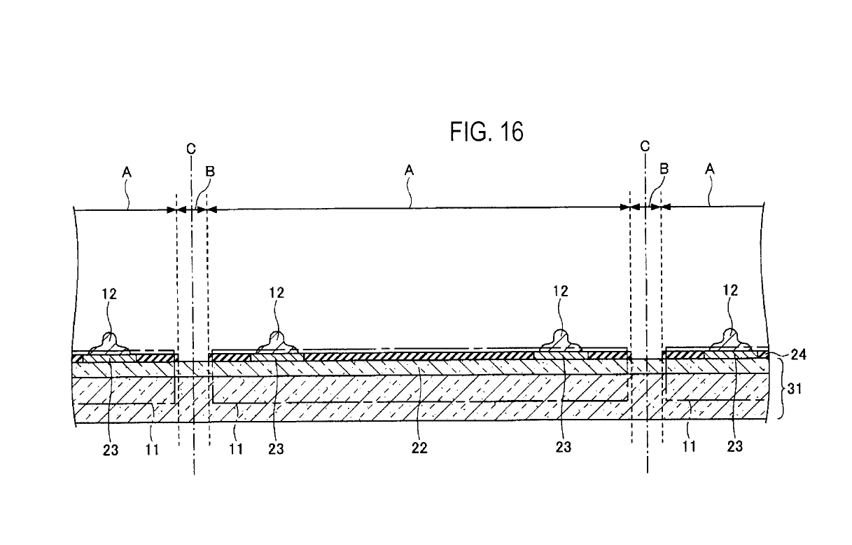

Then, in steps shown in FIG. 16, the internal connection terminal 12 is formed on a plurality of electrode pads 23 provided in a plurality of semiconductor chip forming areas A respectively. As the internal connection terminal 12, for example, the Au bump, the bump consisting of a Ni film formed by the electroless plating and an Au film stacked on this Ni film, or the like can be employed. The Au bumps can be formed by the bonding method, for example. In this case, there is a variation in height of a plurality of internal connection terminals 12 formed in steps shown in FIG. 16.

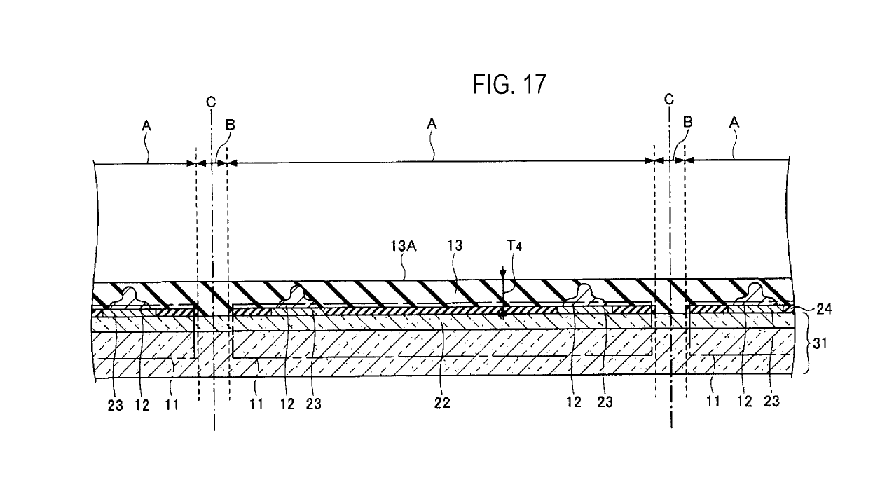

Then, in steps shown in FIG. 17, the insulating layer 13 is formed to cover the semiconductor chip 11 on the side on which the internal connection terminals 12 are provided and the internal connection terminals 12. As the material of the insulating layer 13, either of the photosensitive insulating material and the non-photosensitive insulating material (insulating material having no photosensitivity) may be employed. As the insulating layer 13, for example, a sheet-like insulating resin (e.g., NCF (Non Conductive Film)) in a B-stage state (semi-cured state) having tackiness, a paste-like insulating resin (e.g., NCP (Non Conductive Paste)), a sheet-like anisotropic conductive resin (e.g., ACF (Anisotropic Conductive Film)) having tackiness, a build-up resin (an epoxy resin with filler or an epoxy resin without filler), a liquid crystal polymer, and the like can be listed. ACP and ACF are formed by dispersing small spherical resins coated by Ni/Au into an insulating resin using an epoxy-based resin as a base, and these resins have a conductivity in the vertical direction and have an insulating property in the horizontal direction.

When a sheet-like insulating resin having tackiness is employed, the insulating layer 13 is formed by pasting a sheet-like insulating resin on the upper surface side of a structure shown in FIG. 16. Also, when a paste-like insulating resin is employed as the insulating layer 13, a paste-like insulating resin is formed on the upper surface side of a structure shown in FIG. 16 by the printing method, or the like, and then the insulating resin is semi-cured by the pre-baking. This semi-cured insulating resin has adhesiveness. A thickness T₄ of the insulating layer 13 can be set to 20 μm to 100 μm, for example.

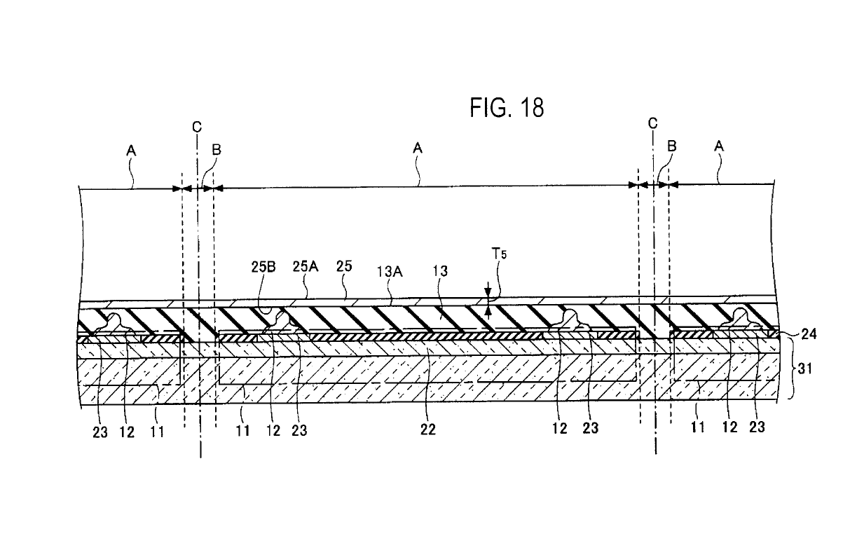

Then, in steps shown in FIG. 18, a plate body 25 is provided onto the upper surface 13A of the insulating layer 13. In the plate body 25, a lower surface 25B on the side that opposes to the upper surface 13A of the insulating layer 13 is formed as a rough surface. A thickness T₅ of the plate body 25 can be set to 10 μm, for example. As the plate body 25, for example, a metallic foil such as a Cu foil, or the like can be employed. Also, a temporary film made of PET, or the like may be employed as the plate body 25. Also, a resin film with single-sided copper foil, in which a Cu foil is provided previously on one surface of a resin film, can be employed. Here, steps will be explained hereunder by taking as an example the case where the metallic foil is employed as the plate body 25.

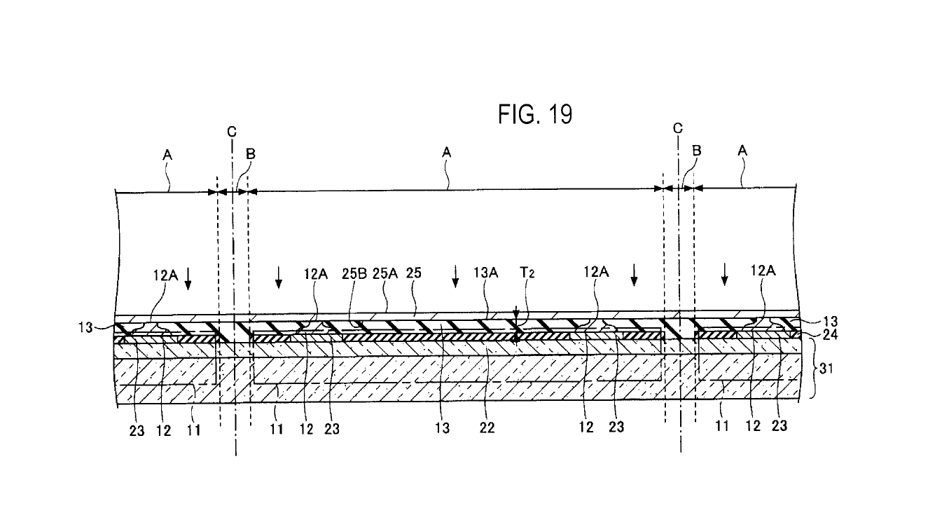

Then, in steps shown in FIG. 19, the plate body 25 is press-bonded to the insulating layer 13 by pressing the plate body 25 from the upper surface 25A side of the plate body 25 in a state that a structure shown in FIG. 18 is heated. Accordingly, the insulating layer 13 is pressed, and the upper surface 12A of the internal connection terminal 12 is exposed from the upper surface 13A of the insulating layer 13. Also, the rough surface of the lower surface 25B of the plate body 25 is transferred onto the upper surface 13A of the insulating layer 13. The insulating layer 13 is cured after the press bonding. A thickness T₂ of the insulating layer 13 that underwent the press bonding can be set to 10 μm to 60 μm, for example.

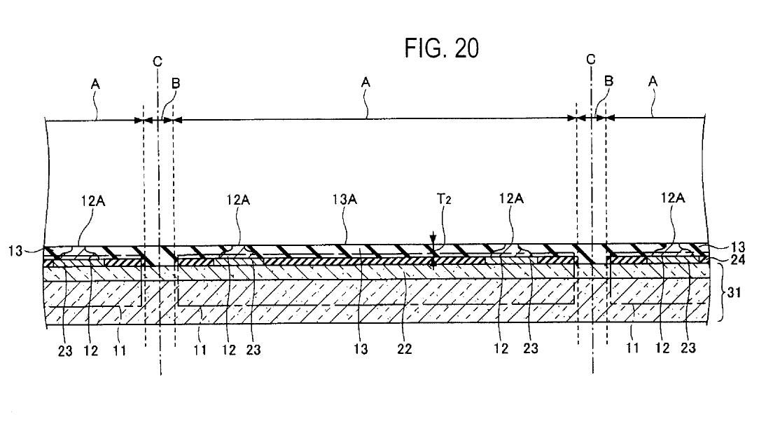

Then, in steps shown in FIG. 20, the plate body 25 is removed completely by the etching. According to steps shown in FIG. 18 to FIG. 20, adhesion between the metal layer 26 and the internal connection terminals 12 can be enhanced in steps described later.

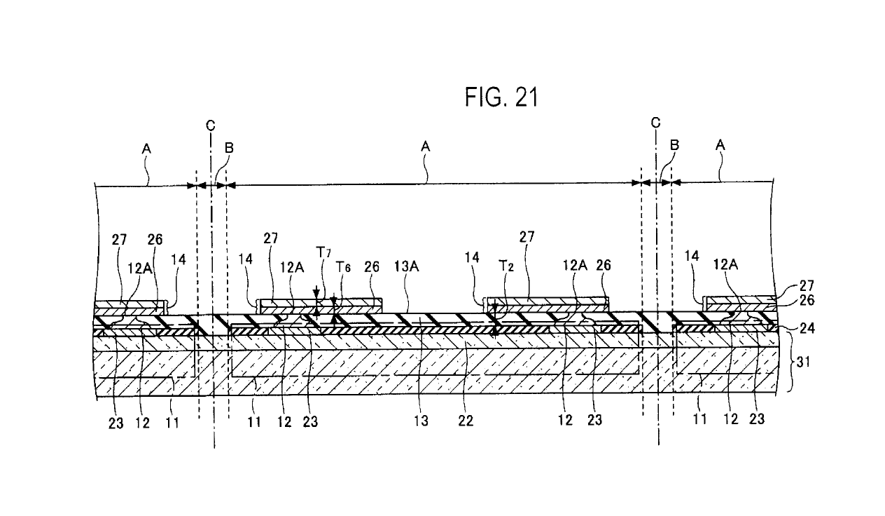

Then, in steps shown in FIG. 21, the wiring patterns 14 each having the metal layer 26 and the metal layer 27 to contact the upper surface 12A of the internal connection terminal 12 are formed on the upper surface 13A of the insulating layer 13. The wiring patterns 14 are connected electrically to the semiconductor integrated circuit 22 via the internal connection terminals 12. As the material of the wiring pattern 14, for example, Cu, or the like can be employed. A thickness of the wiring pattern 14 can be set to 12 μm, for example.

Concretely, the wiring patterns 14 are formed as follows. At first, the metal layers 26 are formed on the upper surface 13A of the insulating layer 13 by the sputter method, or the like. The metal layer 26 and the internal connection terminal 12 are connected electrically to each other. As the metal layer 26, for example, a Cu layer, a stacked layer consisting of a Cu layer and a Cr layer, a stacked layer consisting of a Cu layer and a Ti layer, or the like can be employed. Also, an electroless Cu plating layer, a metal thin film layer formed by the vapor evaporation method, the coating method, the chemical vapor deposition method (CVD), or the like, or a combination of the above metal layer forming methods may be employed. A thickness T₆ of the metal layers 26 can be set to 0.6 μm, for example.

Then, the metal layer 27 is formed by the electroplating method using the metal layers 26 as a power feeding layer, or the like to cover the upper surface of the metal layer 26. As the metal layer 27, for example, Cu, or the like can be employed. A thickness T₇ of the metal layer 27 can be set to 10 μm, for example. Then, a resist film is formed on upper portions of the metal layers 27 corresponding to the forming areas of the wiring patterns 14, by coating a resist on the upper surfaces of the metal layers 27, and then exposing/developing this resist by means of the photolithography method.

Then, the portions of the metal layer 26 and the metal layer 27, on which the resist film is not formed, are removed by etching the metal layer 26 and the metal layer 27 using the resist film as a mask. Thus, the wiring patterns 14 are formed. Then, the resist film is removed. Then, the roughing process is applied to the wiring patterns 14. The roughing process of the wiring patterns 14 can be applied by the method such as the blackening process, the roughing etching process, or the like. The roughing process is applied to improve the adhesion between the solder resist layer 16 formed on the upper surface and the side surface of the wiring patterns 14 and the wiring patterns 14.

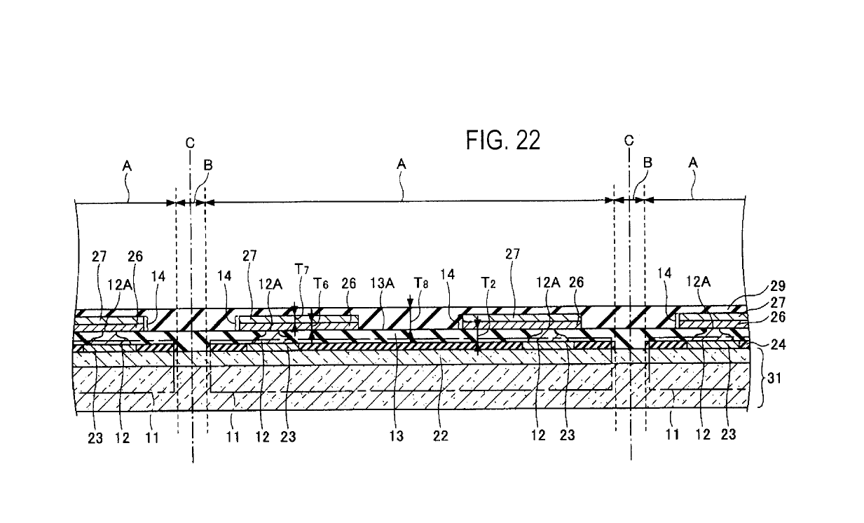

Then, in steps shown in FIG. 22, a cover layer 29 is formed by the printing method, the laminate method, or the like, for example, to cover the upper surface of a structure shown in FIG. 21 (the upper surface 13A of the insulating layer 13 and the wiring patterns 14). As the material of the cover layer 29, any material may be employed if such material can withstand the blast process in steps described later. In this case, polyimide, resist, polyester, polytetrafluoroethylene, or the like, for example, can be employed. A thickness T₈ of the cover layer 29 can be set to 30 μM, for example. In the following steps, the case where a photosensitive resist is employed as the material of the cover layer 29 will be explained.

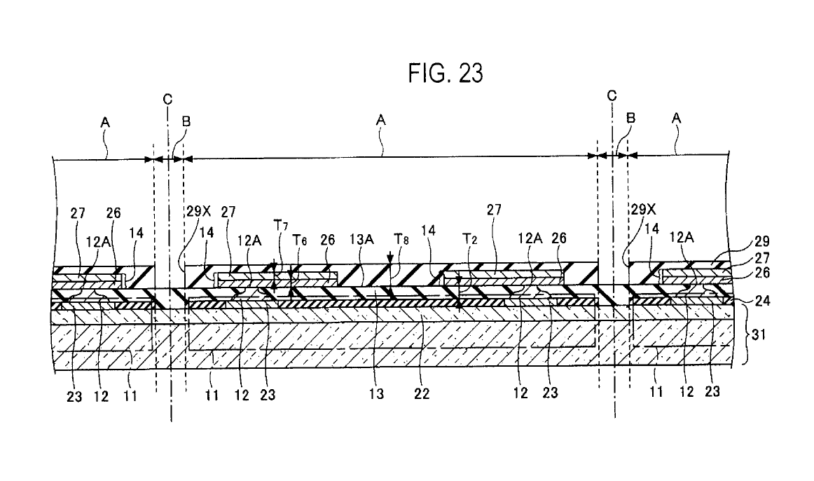

Then, in steps shown in FIG. 23, the cover layer 29 provided on a structure shown in FIG. 22 is exposed via a predetermined mask, and then the cover layer 29 that is subjected to the exposing process is developed. Thus, opening portions 29X from which all or a part of the scribe area B is exposed (the substrate cutting positions C are always exposed) are formed in the cover layer 29. In this case, a metal, a rubber sheet, or the like in which the opening portions 29X are formed previously may be employed as the cover layer 29.

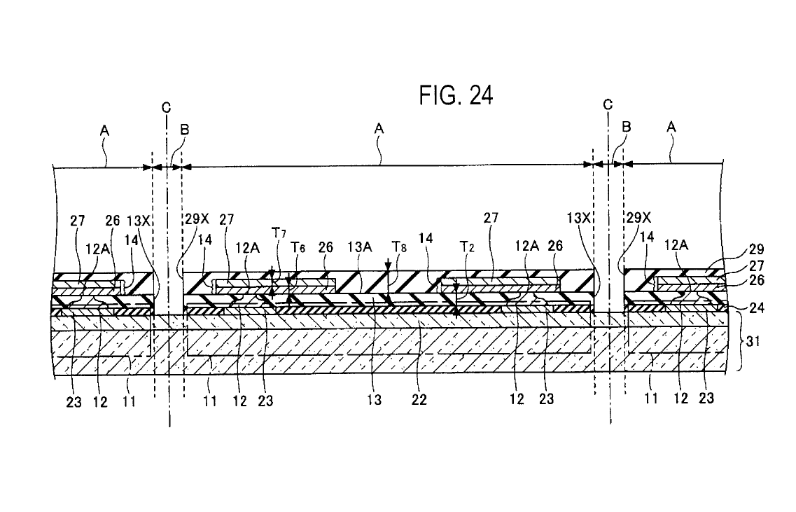

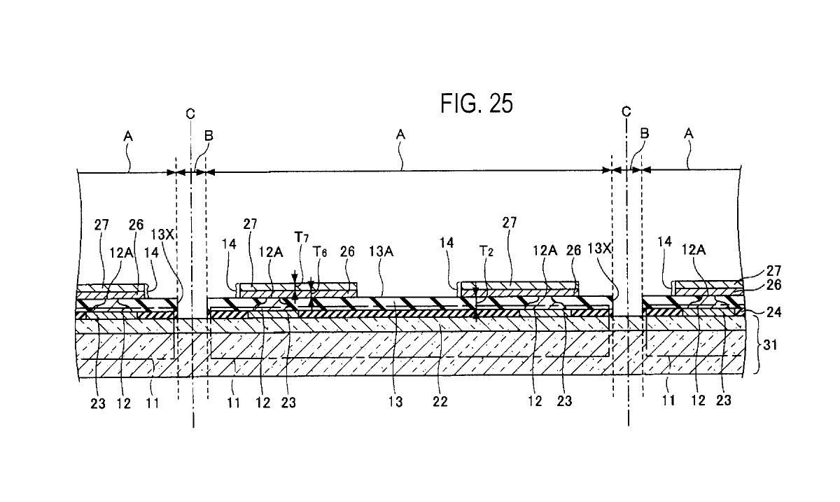

Then, in steps shown in FIG. 24, portions of the insulating film 13 corresponding to the opening portions 29X are removed by applying the blast process to a structure shown in FIG. 23 while using the cover layer 29 as a mask, and thus opening portions 13X are formed in the insulating film 13. The blast process denotes such a method that the surface of the object is processed by blasting the blast material to the surface of the object by using the blast machine. As an example of the blast process, for example, the sand blast for causing the glass beads, or the like to blast to the surface of the object, the air blast for causing the abrasives such as alumina, resin, silicon carbide, or the like to blast to the surface of the object by an compressed air, or the like can be listed. Then, in steps shown in FIG. 25, the cover layer 29 shown in FIG. 24 is removed.

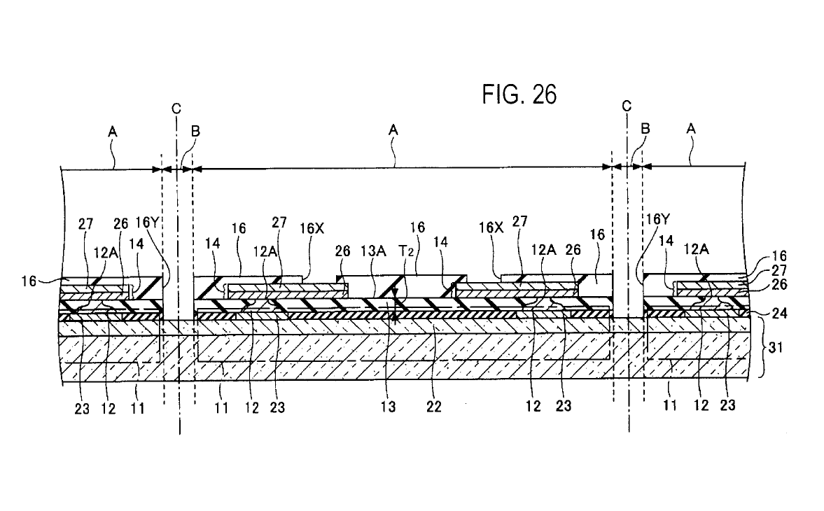

Then, in steps shown in FIG. 26, the solder resist layer 16 is formed to cover the wiring patterns 14 and the upper surface 13A of the insulating layer 13. The solder resist layer 16 is formed to have the opening portions 16X from which a part of the wiring pattern 14 is exposed respectively, and opening portions 16Y from which all or a part of the scribe area B is exposed respectively. Concretely, at first a photosensitive resin composite, for example, is coated to cover the wiring patterns 14 and the upper surface 13A of the insulating layer 13, then the photosensitive resin composite is exposed/developed by the photolithography method, and then respective portions of the photosensitive resin composite corresponding to the external connection terminals 17 and corresponding to all or a part of the scribe areas B are removed by the etching. Thus, the solder resist layer 16 having the opening portions 16X and the opening portions 16Y is formed.

The opening portions 16Y from which all or a part of the scribe area B is exposed respectively are always formed to expose the substrate cutting positions C. A thickness of the solder resist layer 16 can be set to 50 μm, for example. A width of the scribe area B can be set to 100 μm, for example.

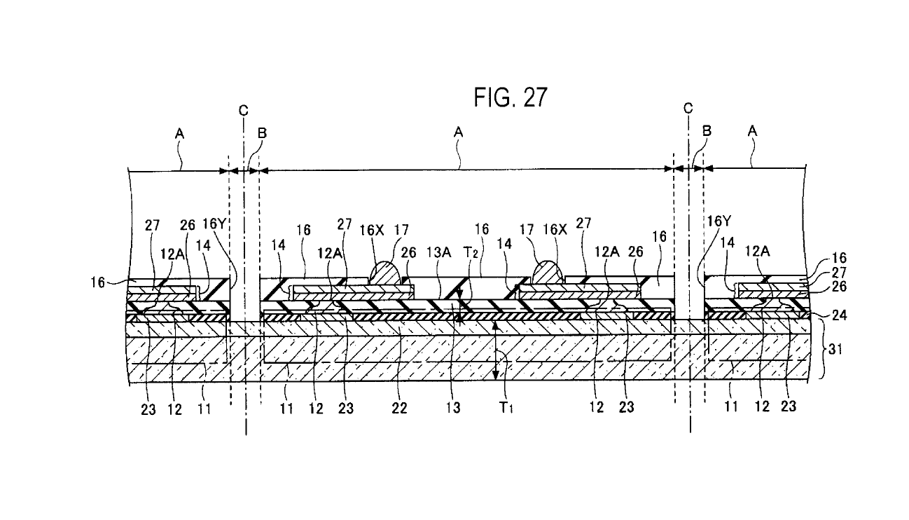

Then, in steps shown in FIG. 27, the external connection terminal 17 is formed on the wiring patterns 14 in the opening portions 16X respectively. As the external connection terminal 17, for example, the solder bump, or the like can be employed. As the material of the external connection terminal 17, for example, alloy containing Pb, alloy of Sn and Cu, alloy of Sn and Ag, alloy of Sn, Ag, and Cu, or the like can be employed. Also, for example, the solder ball (Sn-3.5 Ag) using a resin (e.g., divinylbenzene, or the like) as a core, or the like may be employed. Accordingly, the structure corresponding to the semiconductor device 10 is formed in a plurality of semiconductor chip forming areas A respectively.

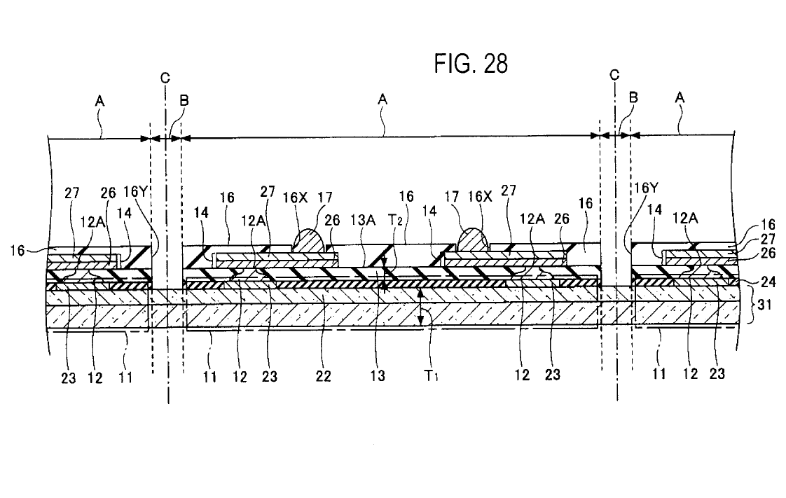

Then, in steps shown in FIG. 28, the semiconductor substrate 31 is thinned by polishing or grinding the other surface (a surface in the side on which the semiconductor integrated circuit 22 is formed) of the semiconductor substrate 31. In the thinning of the semiconductor substrate 31, for example, the backside grinder, or the like can be employed. A thickness T₁ of the semiconductor substrate 31 that underwent the thinning process can be set to 100 μm to 300 μm, for example.

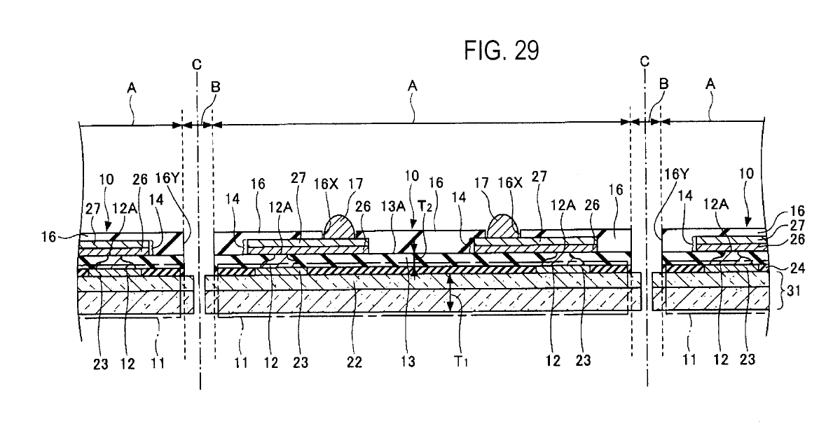

Then, in steps shown in FIG. 29, a plurality of semiconductor devices 10 are manufactured by cutting the semiconductor substrate 31 corresponding to the scribe area B along the substrate cutting position C. The cutting of the semiconductor substrate 31 is executed by the dicing, for example. At this time, the insulating layer 13 and the solder resist layer 16 are not formed in all or a part of the scribe area B of the semiconductor devices 10, but the portions of the insulating layer 13 and the solder resist layer 16 corresponding to the substrate cutting position C are opened surely. Therefore, upon cutting the semiconductor substrate 31 along the substrate cutting position C, only the semiconductor substrate 31 is cut but the insulating layer 13 and the solder resist layer 16 are not cut.

Here, in the case of the conventional semiconductor device in which the insulating layer and the solder resist layer in the portions corresponding to the substrate cutting position C are not opened, in some cases the method called the step cut (only the insulating layer and the solder resist layer are cut by the first blade, and then the semiconductor substrate is cut by the second blade) is employed. In this case, it is difficult to adjust a height of the blade, so that in many cases the insulating layer and the solder resist layer as well as the semiconductor substrate are cut simultaneously. In steps shown in FIG. 29, only the semiconductor substrate 31 is cut whereas the insulating layer 13 and the solder resist layer 16 are not cut. Therefore, the step cut is not needed and thus the cutting step can be simplified.

According to the method of manufacturing the semiconductor device according to the first embodiment of the present invention, in cutting the semiconductor substrate 31 along the substrate cutting position C, only the semiconductor substrate 31 is cut but the insulating layer 13 and the solder resist layer 16 are not cut. As a result, it is made possible that the peeling caused at the boundary between the semiconductor substrate 31 and the insulating layer 13 is hardly occur.

Also, according to the method of manufacturing the semiconductor device according to the first embodiment of the present invention, the insulating layer 13 is removed from the predetermined portion by the blast process. Therefore, there is no need that the photosensitive insulating material should always be selected as the insulating material constituting the insulating layer 13. Also, the non-photosensitive insulating material can be selected, and a margin of design of the insulating layer 13 can be increased. That is, when the photosensitive insulating material is selected as the insulating material constituting the insulating layer 13, the opening portions from which all or a part of the ascribe area B is exposed can be formed by exposing/developing the insulating material constituting the insulating layer 13. However, according to the method of manufacturing the semiconductor device according to the first embodiment of the present invention, either of the photosensitive insulating material and the non-photosensitive insulating material can be employed as the insulating material constituting the insulating layer 13.

### Variation 1 of First Embodiment

In some cases, TEG is formed in the scribe area B of the semiconductor substrate 31. Here, TEG is an abbreviation of the test element group, and is used to check the characteristics of the semiconductor device 10, etc. In a variation 1 of the first embodiment, the cutting step applied when TEG is formed in the scribe area B of the semiconductor substrate 31 will be explained hereunder.

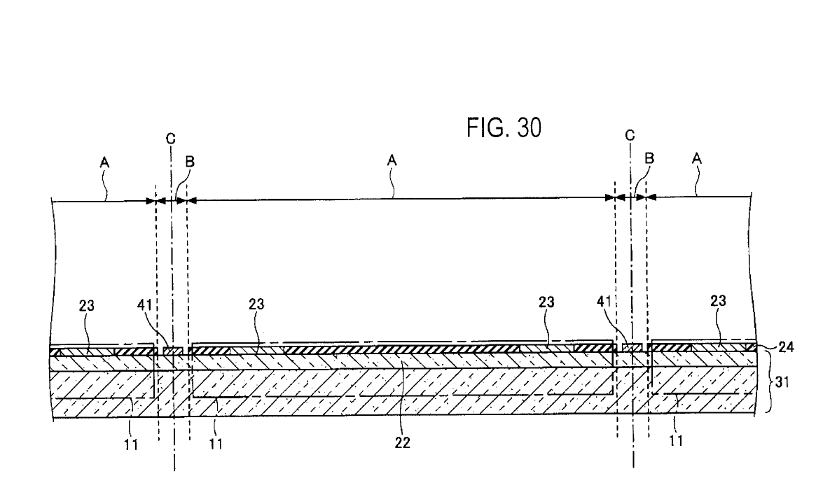

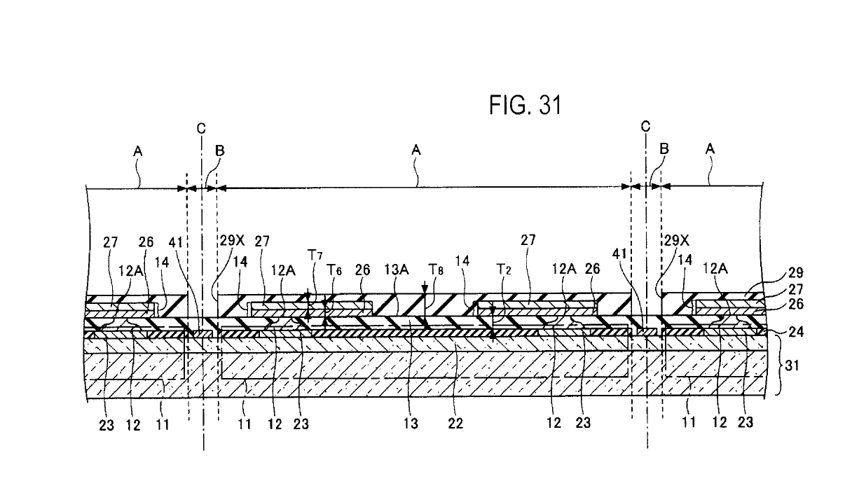

FIG. 30 and FIG. 31 are views showing steps of manufacturing a semiconductor device according to the variation 1 of the first embodiment of the present invention. In FIG. 30 and FIG. 31, the same reference symbols are affixed to the same constituent portions as those in FIG. 14 to FIG. 29 and in some cases their explanation is omitted herein.

At first, after the steps similar to those in FIG. 14 of the first embodiment, in steps shown in FIG. 30, the semiconductor chip 11 is formed on one side of the semiconductor substrate 31 corresponding to the semiconductor chip forming area A by the well-known approaches in the similar steps to those in FIG. 15 of the first embodiment. That is, the semiconductor integrated circuit 22 is formed on one side of the semiconductor substrate 31 prior to the thinning process, and then a plurality of electrode pads 23 and the protection film 24 are formed on one surface (a surface on the side on which the semiconductor integrated circuit 22 is formed) of the semiconductor substrate 31. In this case, the protection film 24 is formed on one surface of the semiconductor substrate 31 except the scribe area B. At this time, a TEG 41 is formed in the scribe area B. As the material of the TEG 41, for example, Al, or the like can be employed, like the material of the electrode pad 23.

Then, after the steps similar to those in FIG. 16 to FIG. 22 of the first embodiment, in steps shown in FIG. 31, the opening portions 29X from which all or a part of the scribe area B is exposed are formed in the cover layer 29 by the similar steps to those in FIG. 23 in the first embodiment. Then, in the steps similar to those in FIG. 24 of the first embodiment, the insulating layer 13 corresponding to the opening portions 29X is removed by applying the blast process to a structure shown in FIG. 31 while using the cover layer 29 as a mask. At this time, the TEG 41 is also removed simultaneously. Then, in the steps similar to those in FIG. 25 to FIG. 29 of the first embodiment, a plurality of semiconductor devices 10 are manufactured.

According to the method of manufacturing the semiconductor device according to the variation 1 of the first embodiment of the present invention, the similar advantages to the method of manufacturing the semiconductor device according to the first embodiment of the present invention can be achieved.

Also, the removal of the TEG 41 is executed in the same step as that applied to remove the insulating layer 13 corresponding to the opening portions 29X. Therefore, there is no necessity to provide the special step of removing the TEG 41.

### Variation 2 of First Embodiment

In steps shown in FIG. 22 of the first embodiment, individual piece like cover layers 33, each size of which corresponds to the semiconductor chip forming area A, may be pasted onto respective semiconductor chip forming areas A instead of the formation of the cover layer 29 to cover the whole upper surface (the upper surface 13A of the insulating layer 13 and the wiring patterns 14) of the structure shown in FIG. 21.

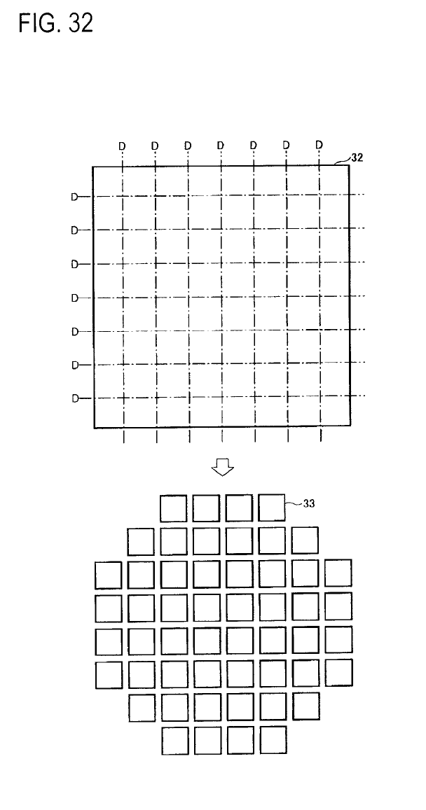

In a variation 2 of the first embodiment, manufacturing steps when the individual piece-like cover layers 33 are employed instead of the cover layer 29 will be explained hereunder. FIG. 32 to FIG. 35 are views showing steps of a variation 2 of the first embodiment of the present invention. In FIG. 32 to FIG. 35, the same reference symbols are affixed to the same constituent portions as those in FIG. 14 to FIG. 29 and in some cases their explanation is omitted herein.

At first, after the steps similar to those in FIG. 14 to FIG. 21 of the first embodiment, in steps shown in FIG. 32, a sheet-like cover layer 32 is prepared. Then, the individual piece-like cover layers 33, each size of which corresponds to the semiconductor chip forming area A, are manufactured by cutting the sheet-like cover layer 32 in positions D by using the die, or the like. Then, the individual piece-like cover layers 33 are rearranged to correspond to a layout of the semiconductor chip forming areas A on the semiconductor substrate 31. As the sheet-like cover layer 32, for example, a sheet-like insulating resin (e.g., NCF (Non Conductive Film)) in a B-stage state (semi-cured state) having tackiness, a sheet-like anisotropic conductive resin (e.g., ACF (Anisotropic Conductive Film)) having tackiness, or the like can be employed.

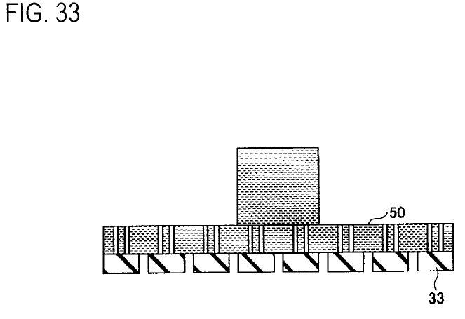

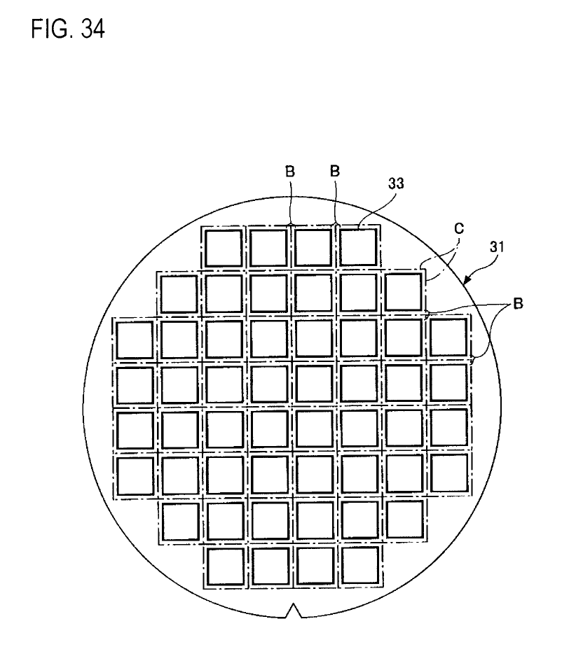

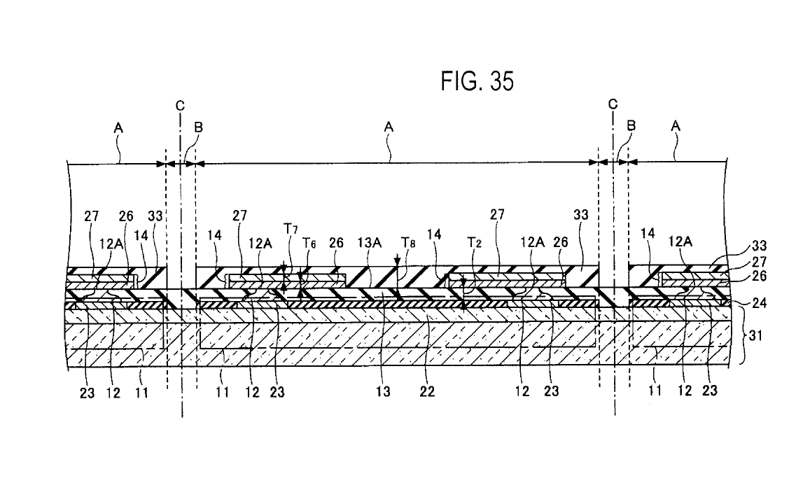

Then, in steps shown in FIG. 33, the individual piece-like cover layers 33 rearranged as shown in FIG. 32 are sucked by a sucking jig 50 and are moved onto the semiconductor substrate 31. Then, in steps shown in FIG. 34 and FIG. 35, the suction of the sucking jig 50 is stopped, and the cover layers 33 are arranged in the semiconductor chip forming areas A to cover the upper surface (the upper surface 13A of the insulating layer 13 and the wiring patterns 14) of the structure shown in FIG. 21. A thickness T₄ of the cover layer 33 can be set to 20 μM to 100 μM, for example.

In this manner, the cover layers 33 are arranged to expose all or a part of the scribe area B (the substrate cutting positions C are always be exposed). Here, FIG. 34 is a plan view and FIG. 35 is a sectional view. Then, in the steps similar to those in FIG. 24 to FIG. 29 of the first embodiment, a plurality of semiconductor devices 10 are manufactured.

According to the method of manufacturing the semiconductor device according to the variation 2 of the first embodiment of the present invention, the similar advantages to the method of manufacturing the semiconductor device according to the first embodiment of the present invention can be achieved.

Also, since the steps of exposing and developing the cover layer are not needed, the manufacturing steps can be simplified.

With the above, the preferred embodiment and variations of the present invention are explained in detail. But the present invention is not limited to the foregoing embodiment and variations. Various modifications and adaptations can be applied to the foregoing embodiment and variations without departing from a scope of the present invention.

For example, in the first embodiment of the present invention, the variation 1 of the first embodiment of the present invention, and the variation 2 of the first embodiment of the present invention, an example in which the wiring patterns (rewirings) are formed on the insulating layer is explained as above. In this case, the present invention intends to prevent the peeling caused at the boundary between the semiconductor substrate and the insulating layer formed on the semiconductor substrate. Therefore, the present invention can be applied to the case where no rewiring is formed if the semiconductor device has the structure that contains the semiconductor substrate and the insulating layer formed on the semiconductor substrate.

Also, in the first embodiment of the present invention, the variation 1 of the first embodiment of the present invention, and the variation 2 of the first embodiment of the present invention, the figures indicating that the opening portions in the insulating layer coincide with the scribe area are employed (for example, FIG. 23, or the like). In this case, the opening portions in the insulating layer may be formed in a mode different from the illustrated mode if all or a part of the scribe area (always including the substrate cutting positions) can be exposed from the opening portions. Also, the opening portions in the insulating layer may be formed wider than the scribe area.

Also, in the first embodiment of the present invention, the variation 1 of the first embodiment of the present invention, and the variation 2 of the first embodiment of the present invention, the method of forming the wiring patterns 14 is not particularly limited. As the method of forming the wiring patterns 14, for example, in steps shown in FIG. 18 and FIG. 19, the metallic foil such as a Cu foil, or the like may be employed as the plate body 25, in addition to the subtractive process, the semi-additive process, etc. Also, in steps shown in FIG. 20, the wiring patterns 14 may be formed by applying the etching the plate body 25 not to remove it.

What is claimed is:

1. A method of manufacturing a semiconductor device, comprising:
a first step of preparing a semiconductor substrate that has a plurality of semiconductor chip forming areas and scribe areas including substrate cutting positions arranged between the plurality of semiconductor chip forming areas;
a second step of forming an insulating layer having first opening portions, which expose all or a part of the scribe areas respectively, on the semiconductor substrate;
a third step of forming a solder resist layer having second opening portions, which expose all or a part of the scribe areas respectively, on the insulating layer; and
a fourth step of cutting portions of the semiconductor substrate corresponding to the substrate cutting positions.

2. A method of manufacturing a semiconductor device, according to claim 1, wherein the insulating layer contains non-photosensitive insulating material.

3. A method of manufacturing a semiconductor device, according to claim 1, wherein, in the second step, the first opening portions are formed by steps including
a step of forming a cover layer, which has third opening portions in positions corresponding to the first opening portions, on the insulating layer, and
a step of removing the insulating layer, which is exposed from the third opening portions, by applying a blast process using the cover layer as a mask.

4. A method of manufacturing a semiconductor device, according to claim 2, wherein, in the second step, the first opening portions are formed by steps including
a step of forming a cover layer, which has third opening portions in positions corresponding to the first opening portions, on the insulating layer, and
a step of removing the insulating layer, which is exposed from the third opening portions, by applying a blast process using the cover layer as a mask.

5. A method of manufacturing a semiconductor device, according to claim 1, wherein, in the second step, the first opening portion is formed by steps including
a step of preparing a film-like insulating resin that is cut into individual pieces, a size of which is set to cover the semiconductor chip forming areas and expose all or a part of the scribe areas, and
a step of pasting the film-like insulating resin to cover the semiconductor chip forming areas and expose all or a part of the scribe areas.

6. A method of manufacturing a semiconductor device, according to claim 2, wherein, in the second step, the first opening portion is formed by steps including
a step of preparing a film-like insulating resin that is cut into individual pieces, a size of which is set to cover the semiconductor chip forming areas and expose all or a part of the scribe areas, and
a step of pasting the film-like insulating resin to cover the semiconductor chip forming areas and expose all or a part of the scribe areas.

7. A method of manufacturing a semiconductor device, according to claim 3, further comprising:
a step of forming a TEG on a part of the scribe areas,
wherein the insulating layer exposed from the third opening portions as well as the TEG is removed by the blast process applied in the second step.

8. A method of manufacturing a semiconductor device, according to claim 4, further comprising:
a step of forming a TEG on a part of the scribe areas,
wherein the insulating layer exposed from the third opening portions as well as the TEG is removed by the blast process applied in the second step.
